(19) United States
(12) Patent Application Publication
(10) Pub. No.: US 2026/0333827 A1
(43) Pub. Date: Oct. 22, 2026

(54) OSCILLATOR, METHOD OF MANUFACTURING THE OSCILLATOR, AND INFORMATION PROCESSING DEVICE

(71) Applicant: Murata Manufacturing Co., Ltd., Nagaokakyo-shi (JP)

(72) Inventors: Sanggyu Koh, Nagaokakyo-shi (JP); Takaaki Miyasako, Nagaokakyo-shi (JP); Tadasu Hosokura, Nagaokakyo-shi (JP)

(21) Appl. No.: 19/696,956

(22) Filed: Jun. 3, 2026

Related U.S. Application Data
(63) Continuation of application No. PCT/JP2024/044391, filed on Dec. 16, 2024.

(30) Foreign Application Priority Data
Dec. 27, 2023 (JP) 2023-220647

(51) Int. Cl. H10D 64/68; G06N 3/063; H03B 5/02; H10D 84/01; H10D 84/80

(52) U.S. Cl. CPC H10D 64/689; G06N 3/063; H10D 84/0149; H10D 84/813; H03B 5/02

(57) ABSTRACT

The present disclosure provides an oscillator using a ferroelectric transistor having a reduced size and a low manufacturing cost, a method of manufacturing the oscillator, and an information processing device. An oscillator includes a semiconductor substrate, a ferroelectric FET that is formed on the semiconductor substrate and that uses a ferroelectric film as a gate insulating film, a paraelectric FET that is formed on the semiconductor substrate and that uses an insulating film made of paraelectrics as a gate insulating film, and a capacitor formed on the semiconductor substrate. In the capacitor, an electrode is opposed to an electrode via at least one of a ferroelectric film, which is the gate insulating film of the ferroelectric FET, and a paraelectric film, which is the gate insulating film of the paraelectric FET.

### CROSS REFERENCE TO RELATED APPLICATIONS

This application is a continuation of International Application No. PCT/JP2024/044391, filed Dec. 16, 2024, which claims priority to Japanese Patent Application No. 2023-220647, filed Dec. 27, 2023, the contents of each of which are hereby incorporated by reference in their entireties.

### TECHNICAL FIELD

The present disclosure relates to an oscillator using a ferroelectric transistor, a method of manufacturing the oscillator, and an information processing device.

### BACKGROUND

Devices (information processing devices) having a function to perform artificial intelligence (AI) processing, which is called edge AI, attract attention in recent years. In particular, in the edge AI, not performance of the entire AI processing using software but performance of part of the AI processing using hardware is proposed to realize power saving and high-speed performance. As for the performance of the AI processing using hardware, a device using a ferroelectric transistor is disclosed in “Experimental Demonstration of Ferroelectric Spiking Neurons for Unsupervised Clustering”, by Wang et al., 2018 IEEE International Electron Devices Meeting (IEDM), December 2018.

Performing the AI processing using an oscillator using a ferroelectric transistor is disclosed in Non Patent Document 1. The oscillator that is disclosed includes a ferroelectric field effect transistor (FET), a discharge FET, and a capacitor. However, in manufacturing of the oscillator, since it is necessary to separately form the ferroelectric FET, the discharge FET, and the capacitor on a substrate, increase in size and increase in manufacturing cost may be brought on.

### SUMMARY OF THE INVENTION

In order to resolve the above problem, it is an object of the present disclosure to provide an oscillator using a ferroelectric transistor having a reduced size and a low manufacturing cost, a method of manufacturing the oscillator, and an information processing device.

An oscillator according to an aspect of the present disclosure includes a substrate, a first field effect transistor that is formed on the substrate and that includes a gate insulating film made of ferroelectrics, a second field effect transistor that is formed on the substrate and that includes a gate insulating film made of paraelectrics, and a capacitor that is formed on the substrate. The first field effect transistor includes a first gate electrode, a ferroelectric film formed over the first gate electrode, a first semiconductor film forming a first channel layer formed on the ferroelectric film, and a first source electrode and a first drain electrode formed on the first semiconductor film. The second field effect transistor includes a second semiconductor film forming a second channel layer formed on the ferroelectric film, a second source electrode and a second drain electrode formed on the second semiconductor film, a paraelectric film formed over the second source electrode, the second drain electrode, and the second semiconductor film, and a second gate electrode formed on the paraelectric film. The paraelectric film is further formed over the first source electrode, the first drain electrode, and the first semiconductor film. The capacitor includes a first electrode that is electrically connected to the first source electrode, and a second electrode that is opposed to the first electrode via at least one of the ferroelectric film and the paraelectric film and that is electrically connected to the second source electrode. The first source electrode is electrically connected to the second drain electrode.

A method of manufacturing an oscillator according to an aspect of the present disclosure is a method of manufacturing an oscillator including a substrate, a first field effect transistor that is formed on the substrate and that includes a gate insulating film made of ferroelectrics, a second field effect transistor that is formed on the substrate and that includes a gate insulating film made of paraelectrics, and a capacitor that is formed on the substrate. The method of manufacturing the oscillator includes forming a first gate electrode of the first field effect transistor and a first electrode of the capacitor on the substrate; forming a ferroelectric film covering the first gate electrode and the first electrode; forming a via extending to the first electrode in the ferroelectric film; forming a first semiconductor film forming a first channel layer of the first field effect transistor on the ferroelectric film; and forming a second semiconductor film forming a second channel layer of the second field effect transistor on the ferroelectric film. The method of manufacturing the oscillator further includes forming a first source electrode and a first drain electrode of the first field effect transistor on the first semiconductor film, forming a second source electrode and a second drain electrode of the second field effect transistor on the second semiconductor film, forming a second electrode of the capacitor on the ferroelectric film, and forming a via conductor with which the first electrode is electrically connected to the first source electrode in the via; forming a paraelectric film covering the first source electrode, the first drain electrode, the second source electrode, the second drain electrode, the second electrode, the first semiconductor film, and the second semiconductor film; and forming a second gate electrode of the second field effect transistor on the paraelectric film.

According to the present disclosure, since the first field effect transistor includes the ferroelectric film formed over the first gate electrode and the second field effect transistor includes a paraelectric film formed over the second semiconductor film formed on the ferroelectric film and the second gate electrode formed on the paraelectric film, it is possible to compose the oscillator using the ferroelectric transistor having a reduced size and a low manufacturing cost.

### BRIEF DESCRIPTION OF DRAWINGS

In the descriptions that follow, like parts are marked throughout the specification and drawings with the same numerals, respectively. The drawings are not necessarily drawn to scale and certain drawings may be illustrated in exaggerated or generalized form in the interest of clarity and conciseness. The disclosure itself, however, as well as a mode of use, further features and advances thereof, will be understood by reference to the following detailed description of illustrative implementations of the disclosure when read in conjunction with reference to the accompanying drawings, wherein:

FIG. 1 is a cross-sectional view for describing the configuration of an oscillator in accordance with aspects of the present disclosure;

FIG. 2 is a circuit diagram of the oscillator in accordance with aspects of the present disclosure;

FIG. 3(a) and FIG. 3(b) include graphs for describing an operation of the oscillator accordance with aspects of the present disclosure;

FIG. 4(a), FIG. 4(b) and FIG. 4(c) include cross-sectional views for describing a method of manufacturing the oscillator in accordance with aspects of the present disclosure;

FIG. 5(a) and FIG. 5(b) include cross-sectional views for describing the method of manufacturing the oscillator in accordance with aspects of the present disclosure;

FIG. 6(a) and FIG. 6(b) include cross-sectional views for describing the method of manufacturing the oscillator in accordance with aspects of the present disclosure; and

FIG. 7 is a schematic diagram of a device using the oscillator in accordance with aspects of the present disclosure.

### DETAILED DESCRIPTION

Hereinbelow, aspects of the present disclosure will be described. In a following description of the drawings, the same or similar components will be represented with use of the same or similar reference characters. The drawings are exemplary, sizes or shapes of portions are schematic, and technical scope of the present disclosure should not be understood with limitation to the aspects.

An oscillator according to an aspect of the present disclosure will herein be described in detail with reference to the drawings. The same reference numerals and symbols represent the same components or equivalent components in the drawings.

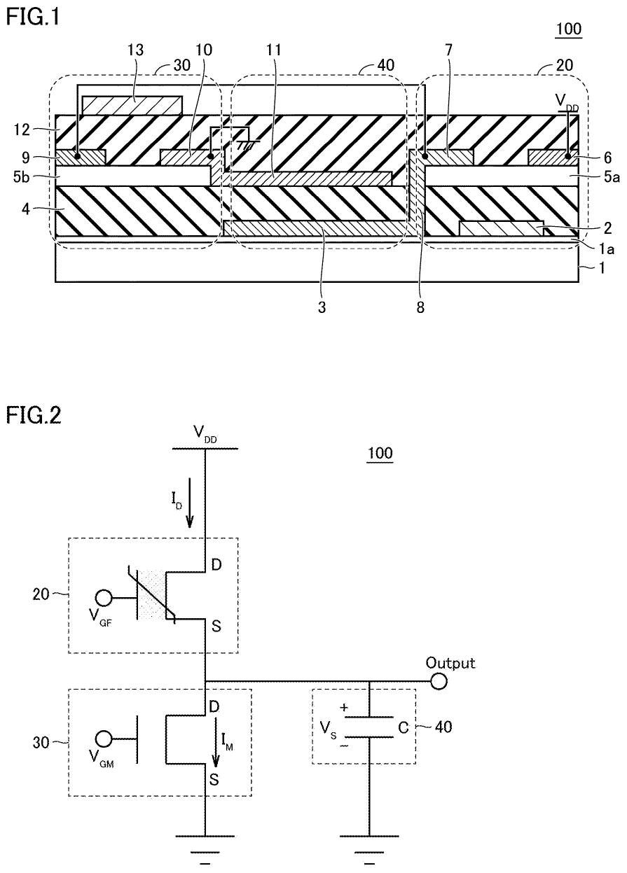

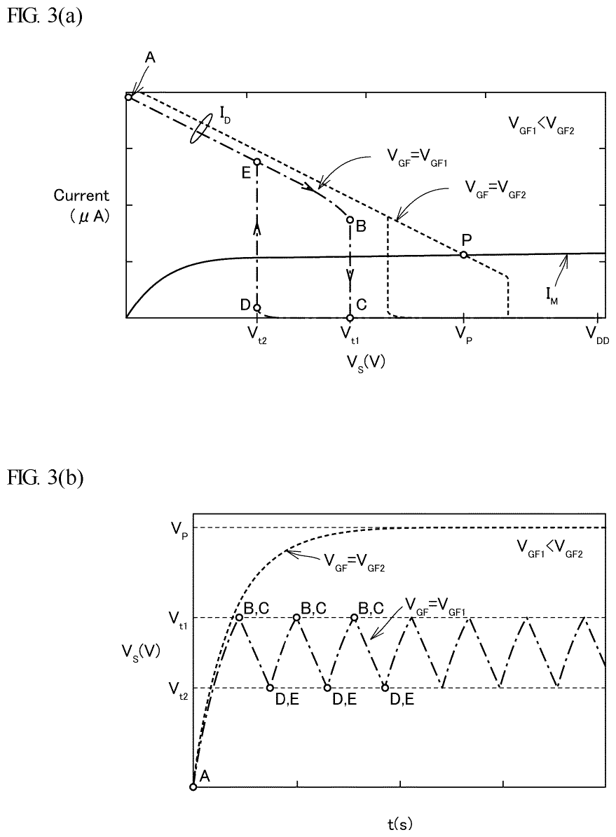

In an aspect of the present disclosure, an oscillator used for, for example, an intermediate layer of the edge AI will be described with reference to the drawings. The oscillator is not limited to being used for the intermediate layer of the edge AI and may be used for other purposes. FIG. 1 is a cross-sectional view for describing the configuration of an oscillator 100 according to an aspect of the present disclosure. FIG. 2 is a circuit diagram of the oscillator 100 according to an aspect of the present disclosure.

The oscillator 100 illustrated in FIG. 1 includes a ferroelectric FET 20 (a first field effect transistor), a paraelectric FET 30 (a second field effect transistor), and a capacitor 40, which are formed on a semiconductor substrate 1. Although the capacitor 40 is provided between the ferroelectric FET 20 and the paraelectric FET 30 in FIG. 1, the layout of the ferroelectric FET 20, the paraelectric FET 30, and the capacitor 40 on the semiconductor substrate 1 is not limited to this. The semiconductor substrate 1 has a passivation film 1a formed on a plane on which the ferroelectric FET 20, the paraelectric FET 30, and the capacitor 40 are provided.

The ferroelectric FET 20 includes a gate electrode 2 (a first gate electrode), a ferroelectric film 4 (a gate insulating film), a channel formation film 5a (a first semiconductor film), a drain electrode 6 (a first drain electrode), and a source electrode 7 (a first source electrode). In the ferroelectric FET 20 illustrated in FIG. 1, the gate electrode 2 is formed on the semiconductor substrate 1, the ferroelectric film 4 and the channel formation film 5a are sequentially formed over the gate electrode 2, and the drain electrode 6 and the source electrode 7 are formed on the ferroelectric film 4 and the channel formation film 5a. In other words, the ferroelectric FET 20 is a bottom-gate field effect transistor.

More specifically, the ferroelectric FET 20 is a metal ferroelectric semiconductor FET (MFSFET). For example, silicon (Si) is used for the semiconductor substrate 1 and the passivation film 1a made of aluminium oxide (Al₂O₃) is formed on the semiconductor substrate 1. The gate electrode 2 is formed on the passivation film 1a using platinum (Pt) in a certain pattern. For example, the ferroelectric film 4 (Ce:HfO₂) in which part of Hf in hafnium oxide is replaced with Ce is used for the gate insulating film. For example, an indium tin oxide (ITO) film (Zr:ITO) to which Zr is added is used for the channel formation film 5a. In the ferroelectric FET 20, the drain electrode 6 and the source electrode 7 are formed on the channel formation film 5a using platinum (Pt) in a certain pattern.

The paraelectric FET 30 includes a channel formation film 5b (a second semiconductor film), a drain electrode 9 (a second drain electrode), a source electrode 10 (a second source electrode), an insulating film 12 (a gate insulating film), and a gate electrode 13 (a second gate electrode). In the paraelectric FET 30 illustrated in FIG. 1, the channel formation film 5b is formed on the ferroelectric film 4, the drain electrode 9 and the source electrode 10 are formed on the channel formation film 5b, and the insulating film 12 and the gate electrode 13 are further sequentially formed. In other words, the paraelectric FET 30 is a top-gate field effect transistor. The insulating film 12 is a paraelectric film.

More specifically, the paraelectric FET 30 is a metal insulator semiconductor FET (MISFET). The paraelectric FET 30 is formed on the ferroelectric film 4. The channel formation film 5b using, for example, an ITO film (Zr:ITO) to which Zr is added is formed on the ferroelectric film 4. The channel formation film 5b is made of the same material as that of the channel formation film 5a and is formed as one film common to the channel formation film 5a. However, the channel formation film 5b may be made of a material different from that of the channel formation film 5a and may be formed as a film different from the channel formation film 5a. Although the channel formation film 5a and the channel formation film 5b are separated from each other in the oscillator 100 illustrated in FIG. 1, the channel formation film 5a and the channel formation film 5b may be joined to each other.

In the paraelectric FET 30, the drain electrode 9 and the source electrode 10 are formed on the channel formation film 5b using platinum (Pt) in a certain pattern. For example, the insulating film 12 made of aluminium oxide (Al₂O₃) is used for the gate insulating film. The gate electrode 13 is formed on the insulating film 12 using platinum (Pt) in a certain pattern. The insulating film 12 (the paraelectric film) is formed so as to not only cover the drain electrode 9, the source electrode 10, and the channel formation film 5b but also further cover the drain electrode 6, the source electrode 7, and the channel formation film 5a. Accordingly, the insulating film 12 functions as the gate insulating film in the paraelectric FET 30 while the insulating film 12 functions as a passivation film that protects the channel formation film 5a in the ferroelectric FET 20. Since the insulating film 12 is formed on the channel formation film 5a, the insulating film 12 is preferably formed using a film formation method that does not generate plasma so as not to damage the channel formation film 5a in the formation of the insulating film 12.

The capacitor 40 includes an electrode 3 (a first electrode) that is electrically connected to the source electrode 7 and an electrode 11 (a second electrode) that is opposed to the electrode 3 via the ferroelectric film 4 and that is electrically connected to the source electrode 10. Although the capacitor 40 has a configuration in which the ferroelectric film 4 is sandwiched between the electrode 3 and the electrode 11, the capacitor 40 may have a configuration in which at least one of the ferroelectric film 4 and the insulating film 12 (the paraelectric film) is sandwiched. Since the ferroelectric film 4 has a relative permittivity higher than that of the insulating film 12, the area of the capacitor 40 may be decreased. Specifically, when hafnium-based ferroelectrics (the relative permittivity: about 30), which are the ferroelectric film, are used between the electrode 3 and the electrode 11, the area of the capacitor 40 may be decreased to about 1/7.5 times, compared with a case in which silicon dioxide (the relative permittivity: about 4), which is the paraelectric film, is used between the electrode 3 and the electrode 11, if the film thickness of the hafnium-based ferroelectrics is equal to that of the silicon dioxide.

The electrode 3 is formed on the passivation film 1a using platinum (Pt) in a certain pattern. The electrode 3 may be formed in the same process as that of the gate electrode 2. The electrode 3 has a via conductor 8 in the ferroelectric film 4 so as to be electrically connected to the source electrode 7. The electrode 11 is formed on the ferroelectric film 4 using platinum (Pt) in a certain pattern. The electrode 11 may be formed in the same process as that of the drain electrodes 6 and 9 and the source electrodes 7 and 10. Part of the electrode 11 or the entire electrode 11 may be formed on the channel formation film 5b.

In the oscillator 100, power supply voltage V_{DD} is supplied to the drain electrode of the ferroelectric FET 20 and the source electrode of the ferroelectric FET 20 is electrically connected to the drain electrode of the paraelectric FET 30, as illustrated in FIG. 2. Accordingly, the power supply voltage V_{DD} is supplied to the drain electrode 6 illustrated in FIG. 1 and the source electrode 7 is electrically connected to the drain electrode 9.

In addition, in the oscillator 100, the source electrode of the ferroelectric FET 20 is electrically connected to one electrode of the capacitor 40 and the other electrode of the capacitor 40 is electrically connected to the source electrode of the paraelectric FET 30 via GND, as illustrated in FIG. 2. Accordingly, the electrode 3 of the capacitor 40 is electrically connected to the source electrode 7 illustrated in FIG. 1 and the source electrode 10 and the electrode 11 of the capacitor 40 are electrically connected to GND.

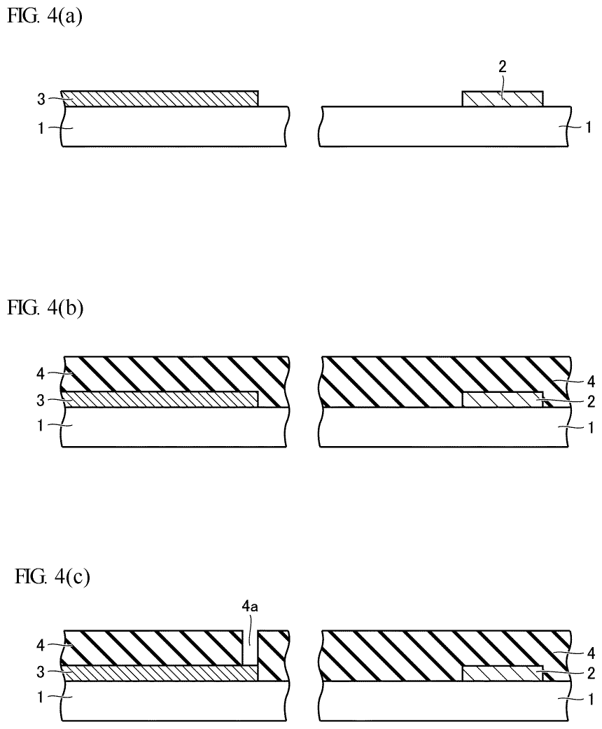

Next, an operation of the oscillator 100 will be described. FIG. 3 includes graphs for describing the operation of the oscillator 100 according to an aspect of the present disclosure. FIG. 3(a) is a graph indicating the relationship between current I_{D} of the oscillator 100 and output voltage V_{S} of the oscillator 100. Referring to FIG. 3(a), the vertical axis represents current and the horizontal axis represents voltage. FIG. 3(b) is a graph indicating how the output voltage V_{S} of the oscillator 100 is varied with respect to time t. Referring to FIG. 3(b), the vertical axis represents voltage and the horizontal axis represents time.

FIG. 3 indicates a waveform (a schematic diagram) when gate voltage V_{GF} of the ferroelectric FET 20 is varied from V_{GF1} to V_{GF2} (V_{GF1}<V_{GF2}) where V_{DD} denotes the power supply voltage, V_{GM} denotes the gate voltage of the paraelectric FET 30, and C denotes the capacitance of the capacitor 40.

In the oscillator 100, the relationship between the current I_{D} and the output voltage V_{S} indicates a hysteresis loop, as illustrated in FIG. 3(a). The hysteresis loop is shifted to the higher side of the output voltage V_{S} with the increasing gate voltage V_{GF}. Specifically, when the gate voltage V_{GF} is V_{GF1}, the current I_{D} flows into the capacitor 40 through the drain electrode-source electrode of the ferroelectric FET 20 and the capacitor 40 is charged with the current I_{D} to increase the output voltage V_{S}. Since the current I_{D} is difficult to flow with the increasing output voltage V_{S}, the current I_{D} is decreased from a point A illustrated in FIG. 3(a) with the increasing output voltage V_{S}. In addition, when the output voltage V_{S} is Vₜ₁ (a point B), the current I_{D} does not flow through the drain electrode-source electrode of the ferroelectric FET 20 (a point C). When the current I_{D} does not flow, the capacitor 40 discharges to cause the output voltage V_{S} to be decreased to Vₜ₂ (a point D). When the output voltage V_{S} is decreased to Vₜ₂, the current I_{D} starts to flow and the capacitor 40 starts to be charged at a point E to increase the output voltage V_{S}.

As described above, when the gate voltage V_{GF} is V_{GF1}, the relationship between the current I_{D} and the output voltage V_{S} indicates the hysteresis loop from the point B to the point E. The oscillator 100 repeats a state in which the output voltage V_{S} is Vₜ₁ (the point B and the point C) and a state in which the output voltage V_{S} is Vₜ₂ (the point D and the point E), as illustrated in FIG. 3(b). In other words, the oscillator 100 outputs a signal in which the output voltage V_{S} repeats the change from Vₜ₁ to Vₜ₂ at regular intervals.

In contrast, when the gate voltage V_{GF} is V_{GF2}, current I_{M} flowing through the drain electrode-source electrode of the paraelectric FET 30 becomes dominant before the current I_{D} stops flowing through the drain electrode-source electrode of the ferroelectric FET 20 (a point P). Accordingly, when the gate voltage V_{GF} is V_{GF2}, the oscillator 100 outputs a signal in which the output voltage V_{S} becomes constant voltage V_{P} without oscillation.

Next, a method of manufacturing the oscillator 100 will be described with reference to the drawings. FIG. 4 to FIG. 6 include cross-sectional views for describing the method of manufacturing the oscillator 100 according to an of an aspect of the present disclosure. First, in FIG. 4(a), the gate electrode 2 and the electrode 3, which are made of platinum (Pt), are formed on one surface of the prepared semiconductor substrate 1 made of silicon (Si). Referring to FIG. 4 to FIG. 6, the left-side area is an area where the capacitor 40 is formed and the right-side area is an area where the ferroelectric FET 20 and the paraelectric FET 30 are formed. Although the gate electrode 2 and the electrode 3 are formed directly on the semiconductor substrate 1, the passivation film 1a may be provided on the semiconductor substrate 1 and the gate electrode 2 and the electrode 3 may be formed on the passivation film 1a.

Specifically, in the formation of the gate electrode 2 and the electrode 3, first, photoresist of a certain pattern is formed on one surface of the semiconductor substrate 1 using a photolithographic technique. Then, a film of platinum (Pt) is formed on one surface of the semiconductor substrate 1 through, for example, radio frequency (RF) sputtering and the photoresist is removed using a liftoff technique to form the gate electrode 2 and the electrode 3.

In FIG. 4(b), the ferroelectric film 4 is formed over the surface of the semiconductor substrate 1 on which the gate electrode 2 and the electrode 3 are formed. The ferroelectric film 4 on the gate electrode 2 composes the gate insulating film of the ferroelectric FET 20 and the ferroelectric film 4 on the electrode 3 composes an insulating body of the capacitor 40. Specifically, the ferroelectric film 4 is formed by forming a film of Ce:HfO₂ on the surface of the semiconductor substrate 1 covering the gate electrode 2 and the electrode 3 using, for example, chemical solution deposition (CSD).

In FIG. 4(c), a via hole 4a is formed in the ferroelectric film 4 on the electrode 3 in the area where the capacitor 40 is formed. Specifically, photoresist of a certain pattern is formed on the ferroelectric film 4 using the photolithographic technique and the ferroelectric film 4 is removed through dry etching to form the via hole 4a.

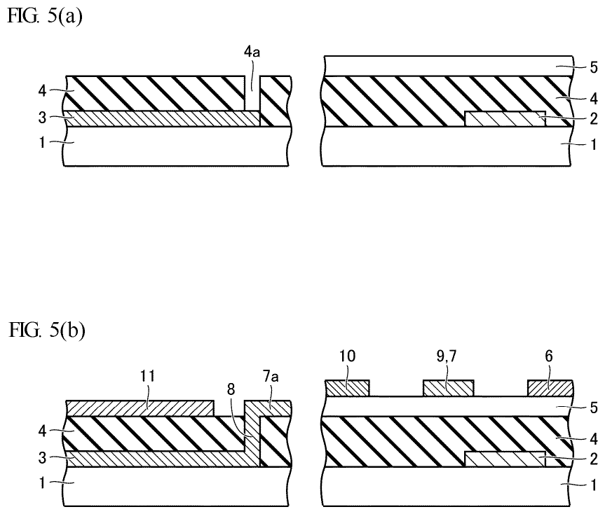

Next, in FIG. 5(a), a channel formation film 5 (including the channel formation films 5a and 5b illustrated in FIG. 1) is formed over the ferroelectric film 4 in the area where the ferroelectric FET 20 and the paraelectric FET 30 are formed. Specifically, the channel formation film 5 is formed by forming an ITO film over the ferroelectric film 4 using sputtering. Although the channel formation film 5 is formed only in the area where the ferroelectric FET 20 and the paraelectric FET 30 are formed in FIG. 5(a), the channel formation film 5 may be formed in the area where the capacitor 40 is formed.

In FIG. 5(b), the drain electrodes 6 and 9 and the source electrodes 7 and 10, which are made of platinum (Pt), are formed on the channel formation film 5 in the area where the ferroelectric FET 20 and the paraelectric FET 30 are formed. In addition, in the area where the capacitor 40 is formed, an electrode 7a and the electrode 11, which are made of platinum (Pt), are formed on the ferroelectric film 4 and the via conductor 8 made of platinum (Pt) is formed in the via hole 4a. The electrode 7a is a portion which is electrically connected to the via conductor 8 and the electrode 3 and with which the via conductor 8 and the electrode 3 are electrically connected to the source electrode 7 and the drain electrode 9.

Specifically, in the formation of the drain electrodes 6 and 9 and the source electrodes 7 and 10, first, photoresist of a certain pattern is formed on the channel formation film 5 using the photolithographic technique. Then, a film of platinum (Pt) is formed through, for example, the radio frequency (RF) sputtering and the photoresist is removed using the liftoff technique to form the drain electrodes 6 and 9 and the source electrodes 7 and 10. Since the source electrode 7 is electrically connected to the drain electrode 9, the source electrode 7 and the drain electrode 9 are illustrated as one electrode in FIG. 5(b). In the formation of the electrodes 7a and 11 and the via hole 4a, photoresist of a certain pattern is formed on the ferroelectric film 4 using the photolithographic technique. Then, a film of platinum (Pt) is formed through, for example, the radio frequency (RF) sputtering and the photoresist is removed using the liftoff technique to form the electrodes 7a and 11 and the via hole 4a.

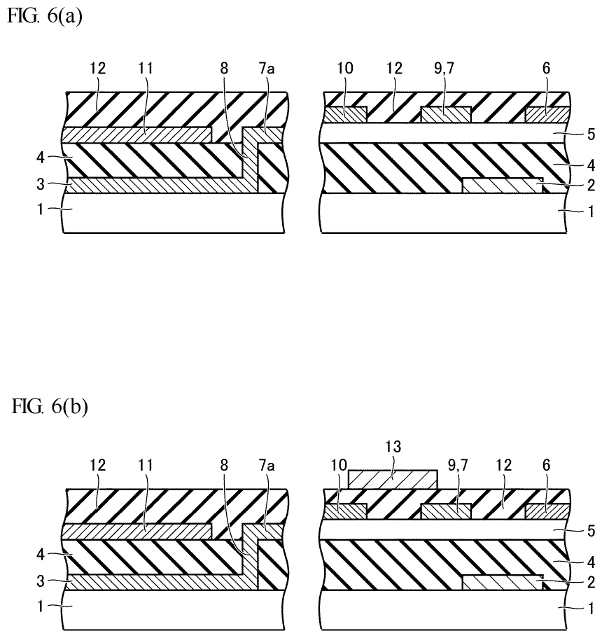

In FIG. 6(a), the insulating film 12 is formed over the channel formation film 5 on which the drain electrodes 6 and 9 and the source electrodes 7 and 10 are formed in the area where the ferroelectric FET 20 and the paraelectric FET 30 are formed. The insulating film 12 is formed over the ferroelectric film 4 on which the electrodes 7a and 11 are formed in the area where the capacitor 40 is formed. Specifically, the insulating film 12 is formed by forming an Al₂O₃ film through, for example, electron cyclotron resonance (ECR) sputtering, which is a film formation method that does not generate plasma. The formation of the insulating film 12 over the channel formation film 5 using the film formation method that does not generate plasma enables the insulating film 12 to be formed without damage to the channel formation film 5.

In FIG. 6(b), the gate electrode 13 made of platinum (Pt) is formed on the insulating film 12 covering the drain electrode 9 and the source electrode 10. Specifically, in the formation of the gate electrode 13, first, photoresist of a certain pattern is formed on the insulating film 12 using the photolithographic technique. Then, a film of platinum (Pt) is formed through, for example, the radio frequency (RF) sputtering and the photoresist is removed using the liftoff technique to form the gate electrode 13.

As described above with reference to FIG. 4 to FIG. 6, the oscillator 100 has the configuration in which the three elements: the ferroelectric FET 20, the paraelectric FET 30, and the capacitor 40 may be concurrently formed on the same semiconductor substrate 1 using the common materials. In particular, the insulating film 12 is configured so as to function as the passivation film protecting the channel portion of the bottom-gate ferroelectric FET 20 and also to function as the gate insulating film of the top-gate paraelectric FET 30. In addition, the ferroelectric film 4 is configured so as to function as the gate insulating film of the ferroelectric FET 20 and also to function as the insulating body of the capacitor 40. Accordingly, since the ferroelectric FET 20 includes the ferroelectric film 4 formed over the gate electrode 2 and the paraelectric FET 30 includes the insulating film 12 formed over the channel formation film 5b formed on the ferroelectric film 4 and the gate electrode 13 formed on the insulating film 12 in the oscillator 100, it is possible to reduce the size of the oscillator 100 and the manufacturing cost of the oscillator 100.

The example is described above in which, in the oscillator 100, the film (Ce:HfO₂) in which part of Hf in hafnium oxide is replaced with Ce is used for the ferroelectric film 4 of the ferroelectric FET 20 and the ITO film (Zr:ITO) to which Zr is added is used for the channel formation film 5 (5a). Combining the ferroelectric film 4 made of metal oxide with the channel formation film 5 (5a) made of metal oxide in the above manner enables high interface quality to be achieved on the interface between the ferroelectric film 4 and the channel formation film 5 (5a).

Although the material used for the ferroelectric film 4 is described as the film (Ce:HfO₂) in which part of Hf in hafnium oxide is replaced with Ce, this is only an example and the material used for the ferroelectric film 4 is not limited to this. For example, the ferroelectric film 4 may be hafnium oxide-based ferroelectrics, a film made of bismuth titanate (BIT) (Bi₄Ti₃O₁₂), or a laminated film including these films. More specifically, the material used for the ferroelectric film 4 may be the hafnium oxide-based ferroelectrics (Ce:HfO₂, Hf_{0.5}Zr_{0.5}O₂, La:HfO₂, Si:HfO₂, Gd:HfO₂, or the like), a film made of lead zirconate titanate (PZT) (Pb(Zrₓ, Ti₁₋ₓ)O₃), bismuth lanthanum titanate (BLT) (Bi₄₋ₓLaₓTi₃O₁₂), strontium bismuth tantalate (SBT) (SrBi₂Ta₂O₉), bismuth ferrite (BFO) (BiFeO₃), or BIT (Bi₄Ti₃O₁₂), or a laminated film including these films.

Although the material used for the channel formation film 5 (5a and 5b) is described as the ITO film (Zr:ITO) to which Zr is added, this is only an example and the material used for the channel formation film 5 (5a and 5b) is not limited to this. For example, the material used for the channel formation film 5 (5a and 5b) may be a film made of indium tin oxide (ITO), lanthanum strontium cobalt oxide (LSCO) (LaₓSr₁₋ₓCuO₄), tin oxide (SnOₓ), zinc oxide (ZnOₓ), indium oxide (InOₓ), indium gallium zinc oxide (InGaZnO), or indium tin zinc oxide (InSnZnO) or a laminated film including these films.

Although the material used for the insulating film 12 is described as aluminium oxide (Al₂O₃), this is only an example and the material used for the insulating film 12 is not limited to this. For example, the material used for the insulating film 12 may be a film made of silicon oxide (SiO₂), silicon nitride (SiN), hafnium oxide (HfO₂), or parylene C (polymer coating film) or a laminated film including these films.

Although the material used for the gate electrodes 2 and 13, the drain electrodes 6 and 9, the source electrodes 7 and 10, and the electrodes 3, 7a, and 11 is described as platinum (Pt), this is only an example and the material used for the gate electrodes 2 and 13, the drain electrodes 6 and 9, the source electrodes 7 and 10, and the electrodes 3, 7a, and 11 is not limited to this. For example, the material used for the gate electrodes 2 and 13, the drain electrodes 6 and 9, the source electrodes 7 and 10, and the electrodes 3, 7a, and 11 may be a film made of iridium (Ir), titanium nitride (TiN), tantalum nitride (TaN), tungsten nitride (WN), iridium oxide (IrOₓ), or lanthanum nickel oxide (LaNiOₓ) or a laminated film including these films.

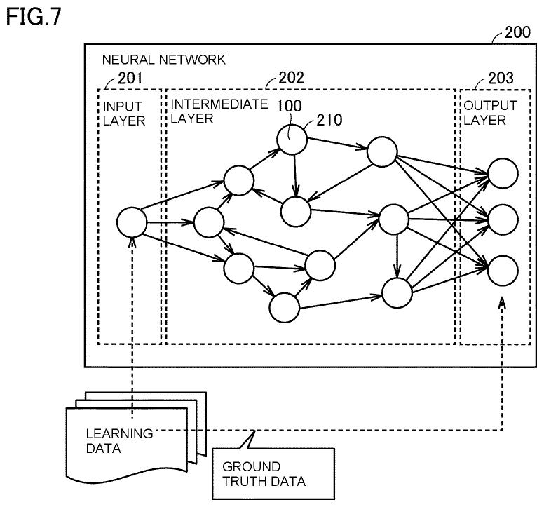

A device 200 (an information processing device) having a function to perform the AI processing using the oscillator 100 described above will now be described. FIG. 7 is a schematic diagram of the device 200 using the oscillator 100 according to an aspect of the present disclosure. The device 200 does not perform the AI processing by accessing the cloud but independently performs the AI processing. The device 200 includes a neural network in order to independently perform the AI processing.

The neural network includes an input layer 201 that accepts input of data (information), an intermediate layer 202 that processes the data, and an output layer 203 that outputs the data. In the device 200, all the AI processing is not processed by software but the intermediate layer 202 is composed of hardware for processing in order to realize power saving and high-speed performance. The device 200 includes an arithmetic unit that processes the hardware portion of the neural network although the arithmetic unit is not illustrated in FIG. 7. The arithmetic unit is composed of a processor, such as a central processing unit (CPU), a microprocessing unit (MPU), a tensor processing unit (TPU), or a graphics processing unit (GPU), a hard-wired circuit, such as an application specific integrated circuit (ASIC) or a field programmable gate array (FPGA), or the like.

Specifically, the intermediate layer 202 is composed of hardware and each node 210 includes the oscillator 100 illustrated in FIG. 1. Each node 210 may include not only the oscillator 100 but also, for example, storage means at the upstream.

In the neural network, the data is input into the input layer 201 where a predetermined weight is added to the data. The value output from the input layer 201 is input into the intermediate layer 202 where a predetermined weight is further added to the value. The value output from the intermediate layer 202 is input into the output layer 203, from which data subjected to the AI processing (for example, an estimation result) is output from the output layer 203. Since the intermediate layer 202 is composed of the hardware including the oscillators 100, as described above, a fixed weight is given to each node 210.

However, since the input layer 201 and the output layer 203 are composed of software, the weight of, for example, a portion from the intermediate layer 202 to the output layer 203 may be updated. In the neural network, the weight of the portion from the intermediate layer 202 to the output layer 203 is updated to greatly reduce the calculation load by the software while keeping the calculation accuracy of the AI processing, thus realizing the power saving and the high-speed performance.

For example, when the estimation result is obtained from the data using the device 200, learning data used for training of the neural network is prepared. The neural network is trained through, for example, supervised learning. In FIG. 7, the learning data including ground truth data is prepared, and the neural network adjusts the weight of the portion from the intermediate layer 202 to the output layer 203 based on the degree of coincidence between the estimation result calculated from the learning data and the ground truth data to perform the training so that the degree of coincidence between the estimation result estimated by the neural network and the ground truth data exceeds a reference value.

The aspects disclosed here are only examples in all points and should be considered not to be restrictive. The scope of the present invention is indicated not by the above description but by the appended claims. Meanings equivalent to the claims and all the modifications within the scope are intended to be included in the present invention.

In general, the description of the aspects disclosed should be considered as being illustrative in all respects and not being restrictive. The scope of the present disclosure is shown by the claims rather than by the above description and is intended to include meanings equivalent to the claims and all changes in the scope. While preferred aspects of the invention have been described above, it is to be understood that variations and modifications will be apparent to those skilled in the art without departing from the scope and spirit of the invention.

### REFERENCE SIGNS LIST

1 semiconductor substrate
1a passivation film
2, 13 gate electrode
3, 7a, 11 electrode
4 ferroelectric film
4a via hole
5, 5a, 5b channel formation film
6, 9 drain electrode
7, 10 source electrode
8 via conductor
12 insulating film
20 ferroelectric FET
30 paraelectric FET
40 capacitor
100 oscillator

1. An oscillator comprising:
a substrate;
a first field effect transistor on the substrate and that includes a gate insulating film comprising ferroelectrics;
a second field effect transistor on the substrate and that includes a gate insulating film comprising paraelectrics; and
a capacitor on the substrate,
wherein the first field effect transistor includes:
a first gate electrode,
a ferroelectric film over the first gate electrode,
a first semiconductor film forming a first channel layer on the ferroelectric film, and
a first source electrode and a first drain electrode on the first semiconductor film, and
wherein the second field effect transistor includes:
a second semiconductor film forming a second channel layer on the ferroelectric film,
a second source electrode and a second drain electrode on the second semiconductor film,
a paraelectric film over the second source electrode, the second drain electrode, and the second semiconductor film, and
a second gate electrode on the paraelectric film.

2. The oscillator according to claim 1, wherein the paraelectric film is further over the first source electrode, the first drain electrode, and the first semiconductor film.

3. The oscillator according to claim 1, wherein the capacitor includes:
a first electrode that is electrically connected to the first source electrode, and
a second electrode that is opposed to the first electrode via at least one of the ferroelectric film and the paraelectric film and that is electrically connected to the second source electrode, and
wherein the first source electrode is electrically connected to the second drain electrode.

4. The oscillator according to claim 1, wherein the second semiconductor film is made of a same material as a material of the first semiconductor film.

5. The oscillator according to claim 4, wherein the second semiconductor film is formed as one film common to the first semiconductor film.

6. The oscillator according to claim 3, wherein, in the capacitor, the first electrode is opposed to the second electrode via the ferroelectric film.

7. The oscillator according to claim 1, wherein the ferroelectric film comprises at least one of hafnium oxide-based ferroelectrics, a film made of bismuth titanate (BIT) (Bi₄Ti₃O₁₂), or a laminated film including these films.

8. A method of manufacturing an oscillator including a substrate, a first field effect transistor that is formed on the substrate and that includes a gate insulating film made of ferroelectrics, a second field effect transistor that is formed on the substrate and that includes a gate insulating film made of paraelectrics, and a capacitor that is formed on the substrate, the method comprising:
forming a first gate electrode of the first field effect transistor and a first electrode of the capacitor on the substrate;
forming a ferroelectric film covering the first gate electrode and the first electrode;
forming a via extending to the first electrode in the ferroelectric film;
forming a first semiconductor film forming a first channel layer of the first field effect transistor on the ferroelectric film;
forming a second semiconductor film forming a second channel layer of the second field effect transistor on the ferroelectric film;
forming a first source electrode and a first drain electrode of the first field effect transistor on the first semiconductor film, forming a second source electrode and a second drain electrode of the second field effect transistor on the second semiconductor film, forming a second electrode of the capacitor on the ferroelectric film, and forming a via conductor with which the first electrode is electrically connected to the first source electrode in the via;
forming a paraelectric film covering the first source electrode, the first drain electrode, the second source electrode, the second drain electrode, the second electrode, the first semiconductor film, and the second semiconductor film; and
forming a second gate electrode of the second field effect transistor on the paraelectric film.

9. The method of manufacturing the oscillator according to claim 8, further comprising forming the first semiconductor film and the second semiconductor film in a same film formation process.

10. The method of manufacturing the oscillator according to claim 8, wherein, in forming the paraelectric film, the paraelectric film is formed using a film formation method that does not generate plasma.

11. The method of manufacturing the oscillator according to claim 8, wherein the capacitor includes a first electrode that is electrically connected to the first source electrode, and a second electrode that is opposed to the first electrode via at least one of the ferroelectric film and the paraelectric film and that is electrically connected to the second source electrode, and wherein the first source electrode is electrically connected to the second drain electrode.

12. The method of manufacturing the oscillator according to claim 8, wherein the second semiconductor film is made of a same material as that of the first semiconductor film.

13. The method of manufacturing the oscillator according to claim 12, further comprising forming the first semiconductor film and the second semiconductor film as one common film.

14. The method of manufacturing the oscillator according to claim 11, wherein, in the capacitor, the first electrode is opposed to the second electrode via the ferroelectric film.

15. The method of manufacturing the oscillator according to claim 8, wherein the ferroelectric film comprises at least one of hafnium oxide-based ferroelectrics, a film made of bismuth titanate (BIT) (Bi4Ti3O12), or a laminated film including these films.

16. An information processing device that processes information using a neural network that includes an input layer, an intermediate layer, and an output layer, wherein the intermediate layer is composed of hardware and each node includes an oscillator, the oscillator comprising:
a substrate;
a first field effect transistor on the substrate and that includes a gate insulating film comprising ferroelectrics;
a second field effect transistor on the substrate and that includes a gate insulating film comprising paraelectrics; and
a capacitor on the substrate,
wherein the first field effect transistor includes:
a first gate electrode,
a ferroelectric film over the first gate electrode,
a first semiconductor film forming a first channel layer on the ferroelectric film, and
a first source electrode and a first drain electrode on the first semiconductor film,
wherein the second field effect transistor includes:
a second semiconductor film forming a second channel layer on the ferroelectric film,
a second source electrode and a second drain electrode on the second semiconductor film,
a paraelectric film over the second source electrode,
the second drain electrode,
the second semiconductor film, and
a second gate electrode on the paraelectric film.

17. The information processing device according to claim 16, wherein the capacitor includes a first electrode that is electrically connected to the first source electrode, and a second electrode that is opposed to the first electrode via at least one of the ferroelectric film and the paraelectric film and that is electrically connected to the second source electrode, wherein the first source electrode is electrically connected to the second drain electrode.

18. The information processing device according to claim 16, wherein the neural network adjusts a weight of a portion from the intermediate layer to the output layer based on a degree of coincidence between an estimation result and ground truth data.

19. The information processing device according to claim 16, further comprising an arithmetic unit composed of at least one of a processor and a hard-wired circuit that processes a hardware portion of the neural network.

20. The information processing device according to claim 16, wherein each node further includes storage means at an upstream of the oscillator.
